(19) United States
(12) Patent Application Publication
(10) Pub. No.: US 2026/0371016 A1
(43) Pub. Date: Nov. 19, 2026

(54) MICRO-ELECTRO-MECHANICAL SYSTEM AND METHOD FOR MANUFACTURING THE SAME

(71) Applicant: UPBEAT TECHNOLOGY Co., Ltd, New Taipei City (TW)

(72) Inventors: Zih-Song HU, New Taipei City (TW); Sung-Cheng LO, New Taipei City (TW); Hsi-Wen TUNG, New Taipei City (TW); Weileun FANG, New Taipei City (TW); Chung-Chieh CHEN, New Taipei City (TW)

(21) Appl. No.: 19/677,279

(22) Filed: May 14, 2026

Related U.S. Application Data
(60) Provisional application No. 63/805,411, filed on May 14, 2025.

(30) Foreign Application Priority Data
Jan. 19, 2026 (TW) 115102051

(51) Int. Cl. H04R 17/00; B81B 3/00; B81C 1/00; H04R 7/04; H04R 7/20; H04R 31/00

(52) U.S. Cl. CPC H04R 17/00; B81B 3/007; B81C 1/00658; H04R 7/04; H04R 7/20; H04R 31/003; H04R 31/006; B81B 2201/0257; B81B 2203/0118; B81B 2203/0127; B81C 2201/0132; H04R 2201/003

(57) ABSTRACT

A micro-electro-mechanical system (MEMS) includes a substrate, a diaphragm, a first cantilever actuator, and a parylene film. The substrate has a cavity. The diaphragm is disposed within the cavity. The first cantilever actuator has one end connected to the substrate and the other end extending into the cavity, and is isolated from the diaphragm by a first gap. The parylene film crosses the first gap, thereby connecting the diaphragm and the cantilever actuator.

This application claims the benefit of U.S. provisional patent application Ser. No. 63/805,411 filed at May 14, 2025, and Taiwan application Serial No. 115102051 filed at Jan. 19, 2026, the subject matter of which are incorporated herein by reference.

### BACKGROUND

### Technical Field

The disclosure relates to an electronic device and a method of manufacturing the same, and in particular to a micro-electro-mechanical system (MEMS) and a method for manufacturing the same.

### Description of Background

With the continuous expansion of artificial intelligence (AI) applications, the demand for acoustic equipment is also increasing. Currently, many acoustic companies are dedicated to meeting consumer needs and supporting AI applications by combining different types of micro-speakers, such as dynamic drivers (DDs) and balanced armatures (BAs), to provide true wireless stereo (TWS) systems, thereby enhancing the sound directivity and fidelity of the same.

Traditional DDs and BAs still have disadvantages such as high power consumption, narrow bandwidth and high assembly complexity. MEMS technology (taking a MEMS micro-speaker as an example) has the potential and advantages for mass production and further miniaturization. Compared with traditional micro-speakers, it consumes less power and does not require a complicated assembly process. In recent years, it has become a solution to replace traditional micro-speakers.

However, the existing MEMS micro-speakers suffer from low sound pressure level (SPL) and the problems of total harmonic distortion (THD). How to further improve the SPL of the MEMS micro-speakers and effectively mitigate the THD problems remains a challenge in this technological field.

Therefore, there is a need of providing an advanced MEMS and a method for manufacturing the same to obviate the drawbacks encountered from the prior art.

### SUMMARY

One aspect of the present disclosure is to provide a MEMS, wherein the MEMS includes a substrate, a diaphragm, a first cantilever actuator, and a parylene film. The substrate has a cavity. The diaphragm is disposed within the cavity. The first cantilever actuator has one end connected to the substrate and the other end extending into the cavity, and is isolated from the diaphragm by a first gap. The parylene film crosses the first gap, thereby connecting the diaphragm and the cantilever actuator.

Another embodiment of the present disclosure, a method for manufacturing a MEMS, wherein the method includes steps as follows: Firstly, a substrate is provided, and a diaphragm is then formed on a front side of the substrate. Next, a first cantilever actuator is formed on the substrate, with one end of the first cantilever actuator connected to the substrate and the other end extending into the position chamber, and to make the first cantilever actuator isolated from the diaphragm by a first gap. Thereafter, a parylene film is formed across the first gap to connect the diaphragm and the cantilever actuator. Subsequently, a portion of the substrate is removed from a back side of the substrate to form a cavity, exposing a portion of the first cantilever actuator, a portion of the parylene film, and the diaphragm.

According to the aforementioned embodiments of the present application, a MEMS and method for manufacturing the same are provided, in which a diaphragm and a cantilever actuator, isolated from each other, are formed within a cavity in a substrate. One end of the cantilever actuator is connected to the substrate, and the other end of the cantilever actuator extends into the cavity. A parylene film is used to connect the cantilever actuator and the diaphragm, thereby suspending the diaphragm within the cavity of the substrate. By using a flexible parylene film serving as the spring structure for driving the diaphragm, a larger displacement output can be generated, while minimizing acoustic losses caused by spring gaps during vibration, thereby improving the SPL of the MEMS.

In addition, since when the piezoelectric layer in the cantilever actuator deforms and bends, the parylene film will be stressed and stretched, thus a certain residual stress can be preserved in the piezoelectric layer that are covered by the parylene film. This can significantly improve the overall stiffness and rigidity of the spring structure and prevent the diaphragm from suffering SPL zero due to the use of a flexible parylene film serving as the diaphragm in the piston-type vibration spring structure. Therefore, it can effectively maintain low-frequency response and expand the bandwidth of the effective SPL of the MEMS.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A is a perspective view illustrating the structure of a MEMS, according to an embodiment of the present disclosure;

FIG. 1B is cross-sectional view illustrating a partial structure of the MEMS taken along the cutting line C1 depicted in FIG. 1A;

FIGS. 2A to 2E are cross-sectional views illustrating a series of process structures for fabricating a MEMS, according to one embodiment of the present disclosure;

FIG. 3 is a cross-sectional view illustrating the structure of a MEMS, according to another embodiment of the present disclosure;

FIG. 4 is a SPL frequency domain diagram (a) and THD domain diagram (b) obtained by measuring one embodiments of micro-speakers that uses the MEMS with the cavity unsealed, as well as measuring a comparative example of a micro-speaker that uses a conventional MEMS, under a driving voltage of 0.7Vᵣₘₛ and a bias voltage of 10V_{DC}; and

FIG. 5 is a SPL frequency domain diagram (a) and THD domain diagram (b) obtained by measuring one embodiments of micro-speakers that uses the MEMS with the cavity completely sealed, as well as measuring a comparative example of a micro-speaker that uses a conventional MEMS, under a driving voltage of 0.7Vᵣₘₛ and a bias voltage of 10 V_{DC}.

### DETAILED DESCRIPTION

The embodiments as disclosed below provide a MEMS and method for manufacturing the same to improve the SPL of the MEMS and effectively maintaining low-frequency response and expanding the bandwidth of the effective SPL. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

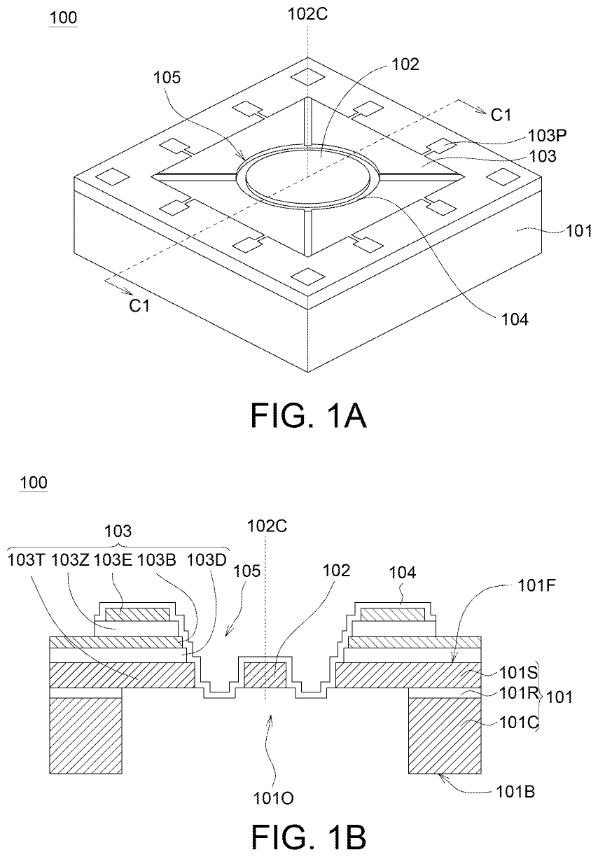

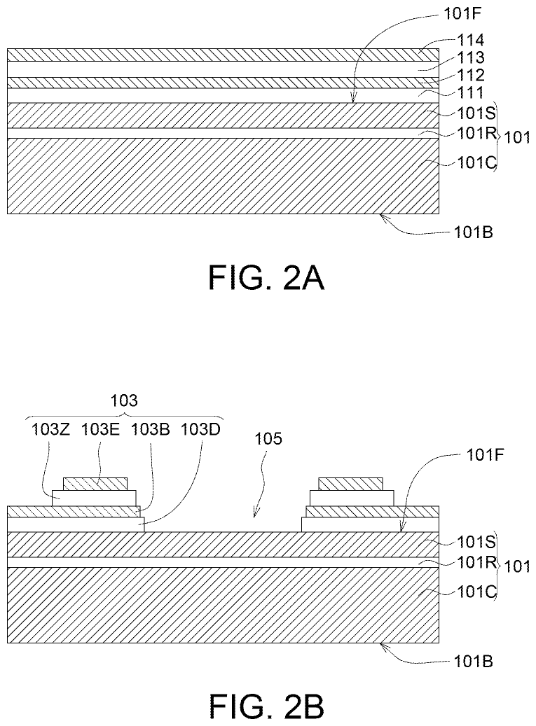

FIG. 1A is a perspective view illustrating the structure of a MEMS 100, according to an embodiment of the present disclosure. FIG. 1B is a cross-sectional view illustrating a partial structure of the MEMS 100 taken along the cutting line C1 depicted in FIG. 1A. In some embodiments of the present disclosure, the MEMS 100 may be a piezoelectric MEMS micro-speakers made using MEMS technology.

In the present embodiment, the MEMS 100 includes a substrate 101, a diaphragm 102, a plurality of (e.g., 4) cantilever actuators 103, and a parylene film 104. The substrate 101 has a hollow cavity 101O. The diaphragm 102 is fixed and suspended within the cavity 101O by the cantilever actuators 103 and the parylene film 104.

In some embodiments of the present disclosure, the substrate 101 may be a silicon-on-insulator (SOI) substrate comprising a silicon base layer 101A, a buried oxide layer 101R, and a silicon device layer 101S. The diaphragm 102 is a portion of the patterned silicon base layer 101C. The diaphragm 102 is isolated from each of the plurality of cantilever actuators 103 by a gap 105 (as shown in FIG. 1A). The gap 105 is a recess formed by removing a portion of the silicon device layer 101S. The cavity 101O is the space resulted from removing a portion of the silicon base layer 101C and a portion of the buried oxide layer 101R, from which a bottom of the diaphragm 102, part of the cantilever actuator 103, and part of the parylene film 104 can be exposed (as shown in FIG. 1B).

The plurality of cantilever actuators 103 are formed on the front side 101F of the substrate 101. Each cantilever actuator 103 includes: a silicon cantilever 103T (of which one end is connected to the diaphragm 102 and the other end extends into the cavity 101O), a patterned dielectric layer 103D disposed on the silicon cantilever 103T, a patterned barrier metal layer 103B disposed above the patterned dielectric layer 103D, a patterned piezoelectric layer 103Z disposed above the patterned barrier metal layer 103B, and a patterned electrode layer 103E disposed above the patterned piezoelectric layer 103Z.

In the present embodiment, the dielectric cantilever 103T of each cantilever actuator 103 is part of the patterned silicon device layer 101S, isolated from the diaphragm 102 by a corresponding gap 105 (as shown in FIG. 1A). In some embodiments of the present disclosure, the width of the gap 105 between each cantilever actuator 103 and the diaphragm 102 can be adjusted according to process requirements or the acoustic standards of the MEMS 100.

The parylene film 104 crosses each gap 105, at least partially covering and securing it above each cantilever actuator 103 and the diaphragm 102. By the connection of the parylene film 104, the diaphragm 102 can be secured and suspended within the cavity 101O (as shown in FIG. 1B).

In the present embodiment, the patterned electrode 103E of each cantilever actuator 103 is electrically connected to an external power source (not shown). When the external power source (not shown) applies a voltage signal to the patterned electrode 103E, stress distribution in the patterned piezoelectric layer 103Z of the corresponding cantilever actuator 103 may be changed to result in deformation of the patterned piezoelectric layer 103Z. This drives the parylene film 104 to provide a driving force perpendicular to the surface of the diaphragm 102, causing the diaphragm 102 to rise or fall along the direction parallel to the central axis 102C of the diaphragm 102, thereby achieving (up-down) piston vibration and generating acoustic pressure.

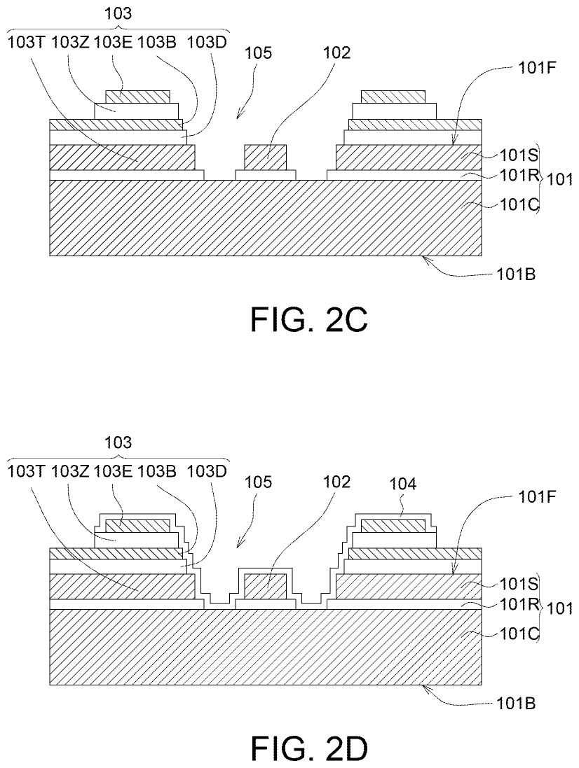

FIGS. 2A to 2E are cross-sectional views illustrating a series of process structures for fabricating the MEMS 100, according to one embodiment of the present disclosure. The method for fabricating the MEMS 100 includes the following steps: Firstly, a substrate 101 with a SOI structure is provided. Then, a diaphragm 102 is formed on the substrate 101, and at least one cantilever actuator 103 is formed on the front side 101F of the substrate 101, so as to make one end of each cantilever actuator 103 away from the diaphragm 102 connected to the substrate 101, and to form a gap 105 isolating the other end of the corresponding cantilever actuator 103 near the diaphragm 102 from the diaphragm 102. The method for forming the diaphragm 102 and the cantilever actuator 103 includes steps as follows:

Firstly, as shown in FIG. 2A, multiple deposition processes are performed to sequentially deposit a dielectric layer 111, a barrier metal layer 112, a piezoelectric layer 113, and a metal layer 114 on the silicon device layer 101S of the substrate 101 at the front side 101F. The dielectric layer 111 comprises silicon oxide. The barrier metal layer 112 comprises platinum (Pt) metal. The piezoelectric layer 113 may comprise lead-zirconate-titanate (PZT) with a high piezoelectric coefficient (d31 coefficient) and significant driving voltage. The metal layer 114 may include a gold/chromium (Au/Cr) bilayer coating.

Then, as shown in FIG. 2B, an etching process (e.g., inductively coupled plasma (ICP) dry etching) is performed to pattern the metal layer 114, the piezoelectric layer 113, the barrier metal layer 112, and the dielectric layer 111, leaving the patterned dielectric layer 103D, the patterned barrier metal layer 103B, the patterned piezoelectric layer 103Z, and the patterned electrode layer 103E, and forming a plurality of gaps 105 to expose a portion of the silicon device layer 101S disposed on the front side 101F of the substrate 101.

Next, as illustrated in FIG. 2C, another etching process (e.g., a reactive-ion etching (RIE) process) is performed to remove a portion of the exposed silicon device layer 101S, so as to deepen the gap 105 to surround a central region of the silicon device layer 101S, thereby defining a diaphragm 102 within the silicon device layer 101S. Meanwhile a plurality of silicon cantilevers 103T are defined in the silicon device layer 101S surrounding the diaphragm 102, but isolated from the diaphragm 102 by the corresponding gaps 105. One of the silicon cantilevers 103T, together with the patterned dielectric layer 103D, patterned barrier metal layer 103B, patterned piezoelectric layer 103Z, and patterned electrode layer 103E that are disposed there above, constitute a cantilever actuator 103.

As illustrated in FIG. 2D, parylene material is deposited to form a parylene film 104, which covers the diaphragm 102, each of the plurality of cantilever actuator 103, and the bottom and sidewalls of the gap 105 disposed between the diaphragm 102 and each of the plurality of cantilever actuator 103. Next, the parylene film 104 is patterned to expose a portion of the patterned electrode layer 103E for use as a bonding pad 103P for electrical connection with an external power source (not shown) (as shown in FIG. 1A).

Subsequently, as shown in FIG. 2E, a deep reactive ion etching (DRIE) process is performed on the back side 101B of the SOI substrate 101 to remove a portion of the silicon base substrate layer 101C, forming a cavity 101O in the substrate 101 and exposing a portion of the buried oxide layer 101R. Then, another RIE process is performed on the back side 101B to remove the exposed portion of the buried oxide layer 101R, so as to partially expose the silicon cantilevers 103T of the cantilever actuators 103, the portion of the parylene film 104 crossing the gap 105, and the bottom of the diaphragm 102. Thus, the diaphragm 102 can be completely separated from the substrate 101, and suspended in the cavity 101O only by the connections with the parylene film 104 and the diaphragm 102, wherein the end of the cantilever actuator 103 near the diaphragm 102 extends into the cavity 101O.

Because the flexible parylene film 104 is used to form a spring structure for driving the diaphragm 102 to vibrate in an up-down piston manner, a larger displacement output can be generated, while minimizing the acoustic loss caused by the spring gap during vibration, thereby improving the SPL of the MEMS 100.

Furthermore, when the piezoelectric layers 103Z of the cantilever actuators 103 deform and bend, the parylene film 104 will be stressed and stretched to preserve a certain residual stress in the piezoelectric layers 103Z that are covered by the parylene film 104. This significantly improves the overall stiffness and rigidity of the spring structure and prevents the diaphragm 102 from suffering SPL zero at high frequencies due to the use of a flexible parylene film 104 serving as the diaphragm 102 in the piston-type vibration spring structure. Therefore, it can effectively maintain low-frequency response and expand the bandwidth of the effective SPL of the MEMS 100. In some embodiments of the present disclosure, using the parylene film 104 to serve as the diaphragm 102 in the piston-type vibration spring structure can increase the resonant frequency of piston mode for the diaphragm 102 from 6.5 kHz to 17.7 kHz.

Of note that, although in the present embodiment the opening of the cavity 101O near the back side 101B of the substrate 101 is not closed, in some other embodiments the opening of the cavity 101O near the back side 101B of the substrate 101 can be completely closed.

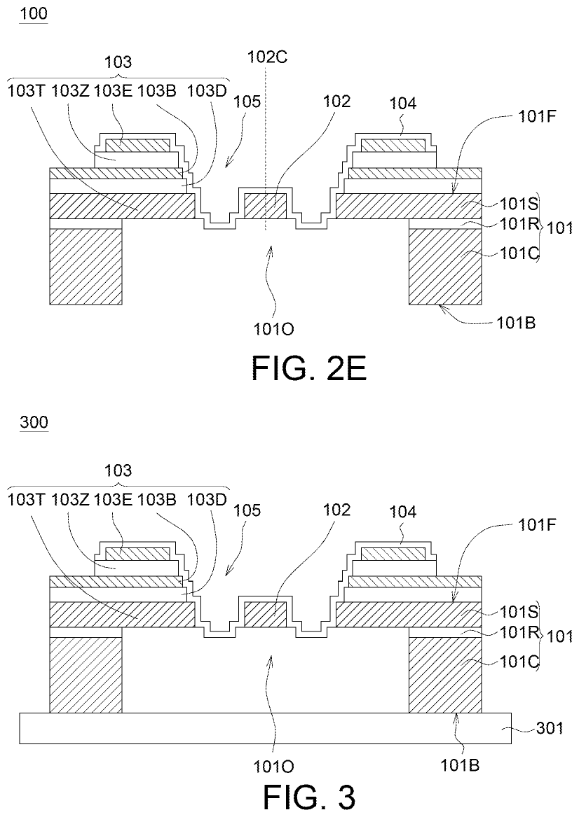

FIG. 3 is a cross-sectional view illustrating the structure of a MEMS 300, according to another embodiment of the present disclosure. The structure of the MEMS 300 is generally similar to that of the MEMS 100 as shown in FIG. 2E. The only difference is that the opening of the cavity 101O of the MEMS 300 near the back side 101B of the substrate 101 is completely sealed by an isolation layer 301. In one embodiment of the present disclosure, the isolation layer 301 may be a dielectric passivation layer or a carrier substrate (e.g., a printed circuit board (PCB)).

The following measurements can further verify the aforementioned technical advantages of the MEMS 100. For example, in some embodiments of the present disclosure, the MEMS 100/300 provided by the aforementioned embodiments and comparative examples can be set as devices under test (DUTs), and connected to printed circuit boards (PCBs) via wire bonding. The PCBs are fixed on a standard ear-simulator (G.R.A.S. RA0401) disposed in an anechoic box. The input signal was provided by a commercial audio analyzer (B&K). The SPL generated by the DUTs are then detected by a standard microphone (G.R.A.S. 40AG) disposed in the standard ear-simulator. Finally, the sound signals are then fed back to an audio analyzer to produce measurements of SPL and THD.

Table 1 shows the measurement conditions and measurements for the micro-speakers using the MEMS 100/300 of the aforementioned embodiments and a comparative example of micro-speakers using a conventional cantilever actuator with a silicon spring structure.

TABLE 1

| | comparative | |
|---|---|---|
| DUT types | example | Embodiments |
| suspending area | 4 | 4 |
| (mm²) | | |
| microphone | 0.7 (+10 Vdc) | 0.7 (+10 Vdc) |
| signal (Vᵣₘₛ) | | |
| | MEMS 100 with the cavity unsealed | |
| SPL bandwidth | 20 KHz-13.7 kHz | 20 Hz-17.7 kHz |
| (SPL >65 dB) | | |
| THD bandwidth | 100 Hz-8.6 kHz | 100 Hz-13.3 kHz |
| (TH <8%) | | |
| | MEMS 300 with the cavity | |
| | completely sealed | |
| SPL bandwidth | 1.8 kHz-15.3 kHz | 20 Hz-20 KHz |
| (SPL >60 dB) | | |
| THD bandwidth | 944 Hz-12.9 kHz | 100 Hz-16.3 kHz |
| (TH <10%) | | |

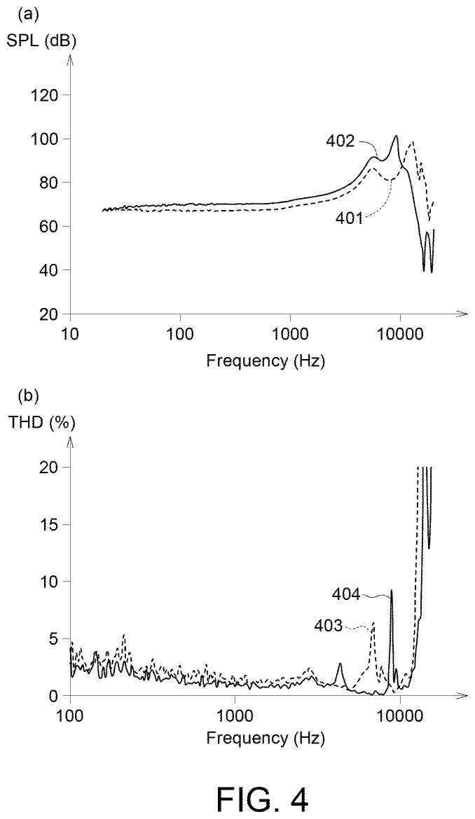

FIG. 4 is a SPL frequency domain diagram (a) and THD domain diagram (b) obtained by measuring one embodiments of micro-speakers that uses the MEMS 100 with the cavity 101O unsealed, as well as measuring a comparative example of a micro-speaker that uses a conventional MEMS, under a driving voltage of 0.7Vᵣₘₛ and a bias voltage of 10V_{DC}.

The measurements show that by comparing the SPL (see curve 401) and THD (see curve 402) obtained by measuring the micro-speakers that uses the MEMS 100 with the cavity 101O unsealed with the SPL (see curve 403) and THD (see curve 404) obtained by measuring the micro-speaker that uses a conventional MEMS, the micro-speakers that uses the MEMS 100 reveal considerably superior performance. In the frequency band between 20 Hz and 17.7 kHz, the SPL of the micro-speakers that uses the MEMS 100 remains greater than 65 dB, and the THD thereof is less than 8%.

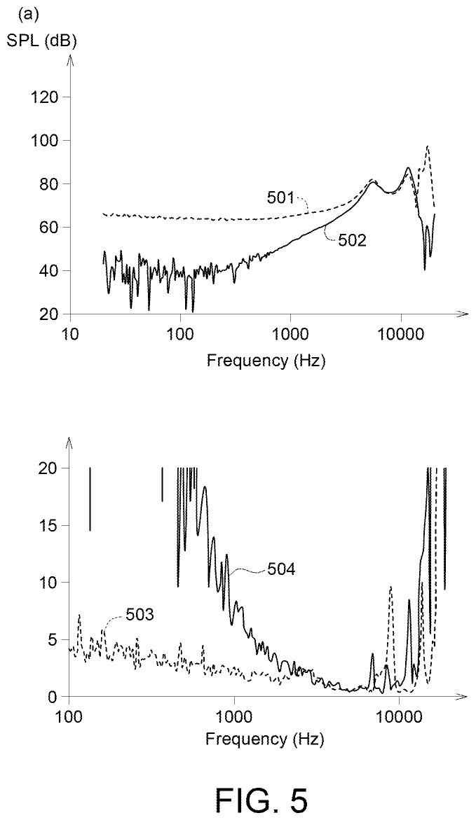

FIG. 5 is a SPL frequency domain diagram (a) and THD domain diagram (b) obtained by measuring one embodiments of micro-speakers that uses the MEMS 300 with the cavity completely sealed, as well as measuring a comparative example of a micro-speaker that uses a conventional MEMS, under a driving voltage of 0.7Vᵣₘₛ and a bias voltage of 10V_{DC}.

The measurements show that the SPL (see curve 501) obtained by measuring the micro-speakers that uses the MEMS 300 with the cavity 101O completely sealed is significantly higher than the SPL (see curve 502) obtained by measuring a comparative example of a micro-speaker that uses a conventional MEMS. This demonstrates that using parylene film 104 serving as the spring structure of the diaphragm 102 can significantly enhance the low-frequency response of the MEMS 300 and effectively suppress acoustic shortcuts caused by the silicon spring gap. Even in the condition as the cavity 101O is completely sealed, the MEMS 300 can still maintain a certain sound pressure performance (e.g. the SPL can still be maintained at more than 60 dB).

Furthermore, the THD (see curve 503) obtained by measuring the micro-speakers that uses the MEMS 300 with the cavity 101O completely sealed is significantly lower than the THD (see curve 504) obtained by measuring a comparative example of a micro-speaker that uses a conventional MEMS. This demonstrates that the MEMS 300 exhibits the same THD performance (<10%) as the MEMS 100 in a narrower frequency band (bandwidth between 0.9 kHz and 12.9 kHz).

Compared to the SPL (see curve 403) and THD (see curve 404) of a conventional microelectromechanical system miniature loudspeaker comparative example. In the frequency band between 20 Hz and 17.7 kHz, the SPL of the microelectromechanical system 100 embodiment remains greater than 65 dB, and the THD is less than 8%.

According to the aforementioned embodiments of the present application, a MEMS and method for manufacturing the same are provided, in which a diaphragm and a cantilever actuator, isolated from each other, are formed within a cavity in a substrate. One end of the cantilever actuator is connected to the substrate, and the other end of the cantilever actuator extends into the cavity. A parylene film is used to connect the cantilever actuator and the diaphragm, thereby suspending the diaphragm within the cavity of the substrate. By using a flexible parylene film serving as the spring structure for driving the diaphragm, a larger displacement output can be generated, while minimizing acoustic losses caused by spring gaps during vibration, thereby improving the SPL of the MEMS.

In addition, since when the piezoelectric layer in the cantilever actuator deforms and bends, the parylene film will be stressed and stretched, thus a certain residual stress can be preserved in the piezoelectric layer that are covered by the parylene film. This can significantly improve the overall stiffness and rigidity of the spring structure and prevent the diaphragm from suffering SPL zero due to the use of a flexible parylene film serving as the diaphragm in the piston-type vibration spring structure. Therefore, it can effectively maintain low-frequency response and expand the bandwidth of the effective SPL of the MEMS.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A micro-electro-mechanical system (MEMS), comprising:
a substrate, having a cavity;
a diaphragm, disposed within the cavity
a first cantilever actuator, having one end connected to the substrate and the other end extending into the cavity, and isolated from the diaphragm by a first gap; and
a parylene film, crossing the first gap, thereby connecting the diaphragm
and the cantilever actuator.

2. The MEMS according to claim 1, wherein the first cantilever actuator comprises:
a silicon cantilever, of which one end is connected to the substrate and another end extends into the cavity;
a patterned piezoelectric layer, disposed above the silicon cantilever; and
a patterned electrode layer, disposed above the patterned piezoelectric layer.

3. The MEMS according to claim 2, wherein the substrate is a silicon-on-insulator (SOI) substrate comprising a silicon device layer; the diaphragm comprises a first portion of the silicon device layer; the silicon cantilever, comprises a second portion of the silicon device layer; and the first portion is separated from the second portion by the first gap.

4. The MEMS according to claim 1, further comprising a second cantilever actuator; wherein one end of the second cantilever actuator is connected to the substrate; another end of the second cantilever actuator extends into the cavity, and the second cantilever actuator is separated from the diaphragm by a second gap.

5. The MEMS according to claim 4, wherein the parylene film covers the first cantilever actuator, the second cantilever actuator, and the diaphragm.

6. A method for fabricating a MEMS, comprising:
providing a substrate;
forming a diaphragm on a front side of the substrate
forming a first cantilever actuator on the substrate, to make one end the first cantilever actuator connected to the substrate, to make another end extending into the cavity, and to make the first cantilever actuator isolated from the diaphragm by a first gap;
forming a parylene film crossing the first gap, thereby connecting the diaphragm and the cantilever actuator; and
removing a portion of the substrate from a back side of the substrate to form a cavity, exposing a portion of the first cantilever actuator, a portion of the parylene film, and the diaphragm.

7. The method according to claim 6, wherein forming the first cantilever actuator comprises:
forming a dielectric layer, a barrier metal layer, a piezoelectric layer, and a metal electrode layer sequentially on one side of the substrate; and
patterning the electrode layer, the piezoelectric layer, the barrier metal layer, and the dielectric layer, simultaneously removing a portion of the substrate to form the first gap on the front side.

8. The method according to claim 6, wherein the substrate is a SOI substrate comprising a silicon device layer and a buried oxide layer; and forming the cavity comprises:
performing a deep reactive ion etching (DRIE) process on the back side to remove a portion of the silicon base substrate layer and expose a portion of the buried oxide layer; and
performing a RIE process on the back side to remove the exposed portion of the buried oxide layer.

9. The method according to claim 6, while forming of the first cantilever actuator, further comprising forming a second cantilever actuator to make one end of the second cantilever actuator connected to the substrate; to make another end of the second cantilever actuator extending into the cavity, and to make the second cantilever actuator separated from the diaphragm by a second gap.

10. The method according to claim 6, wherein forming the parylene film comprises depositing a parylene material to cover the diaphragm, the first cantilever actuator 103, and a bottom and sidewalls of the first gap.
